(19) United States
(12) Patent Application Publication
(10) Pub. No.: US 2015/0060768 A1
(43) Pub. Date: Mar. 5, 2015

(54) METHOD TO IMPROVE PERFORMANCE CHARACTERISTICS OF TRANSISTORS COMPRISING GRAPHENE AND OTHER TWO-DIMENSIONAL MATERIALS

(71) Applicant: The Board of Regents of the University of Texas System, Austin, TX (US)

(72) Inventors: Ananth Dodabalapur, Austin, TX (US); Deji Akinwande, Austin, TX (US); Tae-Jun Ha, Austin, TX (US); Jongho Lee, Austin, TX (US)

(21) Appl. No.: 14/454,422

(22) Filed: Aug. 7, 2014

Related U.S. Application Data
(60) Provisional application No. 61/865,374, filed on Aug. 13, 2013.

(51) Int. Cl. H01L 29/16; H01L 21/02; H01L 29/78; H01L 29/24; H01L 29/06

(52) U.S. Cl. CPC H01L 29/1606; H01L 29/24; H01L 29/0665; H01L 29/78; H01L 21/02527; H01L 21/0212; H01L 21/02282; H01L 21/02381
USPC 257/29; 438/478

(57) ABSTRACT

The electrical properties of graphene and molybdenum sulfide semiconductor devices are improved by incorporating a fluoropolymer capping layer that is in contact with the graphene or molybdenum sulfide layer.

### PRIORITY CLAIM

This application claims priority to U.S. Provisional Application Ser. No. 61/865,374 entitled “METHOD TO IMPROVE PERFORMANCE CHARACTERISTICS OF TRANSISTORS COMPRISING GRAPHENE AND OTHER TWO-DIMENSIONAL MATERIALS” filed Aug. 13, 2013, which is incorporated herein by reference in its entirety

### STATEMENT REGARDING FEDERALLY SPONSORED RESEARCH OR DEVELOPMENT

This invention was made with government support from the National Science Foundation (NSF), Grant numbers EEC-1160494 and EEC-1150034. The U.S. Government has certain rights to this invention.

### BACKGROUND OF THE INVENTION

1. Field of the Invention

The invention generally relates to semiconductor devices. More particularly the invention relates to graphene-based and molybdenum sulfide-based semiconductor devices.

2. Description of the Relevant Art

Graphene is a very promising electronic material because of its high carrier mobility and stable mechanical and chemical properties. Graphene-based field-effect transistors (FETs) have been shown to operate at very high frequencies. Graphene FETs have a high off-current arising from residual carriers as well as the zero-bandgap. It is desirable to seek to transform graphene such that the off-current is reduced. In achieving such a transformation, the high mobility must not be reduced and preferably increased.

There has been a great deal of scientific and technological interest in graphene based field-effect transistors (FETs) due to their unique material and electrical properties. The fabrication of high-quality, large-area graphene layers for device applications has been of considerable interest. Various methods for graphene synthesis have been studied such as mechanical exfoliation, epitaxy and chemical vapor deposition (CVD). CVD graphene is one of the most promising methods of realizing large area graphene and in adapting graphene for silicon CMOS and flexible electronics. The impurities that incorporate in graphene during the transfer and follow-up processes of patterning and lithography affect electrical characteristics such as the position of the Dirac point, field-effect mobility and ON-OFF current ratio.

It is therefore desirable to have a semiconductor device that uses a graphene layer due to the promising electrical properties of this material.

### SUMMARY OF THE INVENTION

In an embodiment, a semiconductor device includes a substrate; a graphene layer disposed on the substrate; and a fluoropolymer or a hydrofluoropolymer layer disposed on the graphene layer. The semiconductor device may be a field-effect transistor. In some embodiments, the graphene layer is monolayer graphene.

In some embodiments, the device comprises a fluoropolymer layer disposed on the graphene layer. Exemplary fluoropolymers that may be used include an ether fluoropolymer, a copolymer of perfluoro-2,2-methyl-1,3-dioxole and perfluoro-2-methylene-4-methyl-1,3-dioxolane (Teflon AF), or CYTOP.

Various substrates may be used including, but not limited to silicon, silicon having a silicon oxide layer disposed between the silicon and the graphene layer, glass, and polymers.

In some embodiments, the semiconductor device includes a first fluoropolymer layer or hydrofluoropolymer layer disposed on the substrate between the substrate and the graphene layer and a second fluoropolymer layer or hydrofluoropolymer layer disposed on the graphene layer.

The semiconductor device may be formed by forming a graphene layer on a substrate and forming a fluoropolymer layer or a hydrofluoropolymer layer on the graphene layer. The fluoropolymer layer or hydrofluoropolymer layer may be formed by applying a solution of the fluoropolymer or hydrofluoropolymer by a spin coating process. In some embodiments, the graphene layer may be formed by: forming a graphene layer on a copper substrate; forming a polymer layer on the graphene layer; separating the polymer layer and graphene layer from the copper substrate; and transferring the polymer layer and graphene layer to the substrate.

In another embodiment, a semiconductor device includes: a substrate; a molybdenum disulfide layer disposed on the substrate; and a fluoropolymer layer or hydrofluoropolymer layer disposed on the molybdenum disulfide layer. The semiconductor device may be a field-effect transistor.

In some embodiments, the device comprises a fluoropolymer layer disposed on the molybdenum disulfide layer. Exemplary fluoropolymers that may be used include an ether fluoropolymer, a copolymer of perfluoro-2,2-methyl-1,3-dioxole and perfluoro-2-methylene-4-methyl-1,3-dioxolane (Teflon AF), or CYTOP.

In some embodiments, the semiconductor device includes a first fluoropolymer layer or hydrofluoropolymer layer disposed on the substrate between the substrate and the molybdenum disulfide layer and a second fluoropolymer layer or hydrofluoropolymer layer disposed on the molybdenum disulfide layer.

In an embodiment, a material is composed of patterned graphene coated with a fluoropolymer layer or a hydrofluoropolymer layer. In some embodiments, the patterned graphene is a graphene nanoribbon.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 depicts a schematic diagram of a transistor that includes a coated graphene layer;

FIG. 2 depicts a schematic diagram of a transistor that includes a graphene layer having top and bottom fluoropolymer or hydrofluoropolymer layers;

FIG. 3 shows the schematic cross-section of a monolayer silicon/silicon oxide graphene FET after capping with the fluoropolymer, CYTOP;

FIGS. 4A and 4B depict a schematic diagram of the processing steps for forming a coated graphene layer on a silicon substrate;

FIG. 5A shows the transfer characteristics of as-deposited monolayer graphene FET without capping with CYTOP, with capping with CYTOP, and after removal of CYTOP;

FIG. 5B shows that the effect on the on-off current ratio after depositing CYTOP on graphene FETs;

FIG. 6 shows the change in the Raman spectrum of monolayer graphene produced by the capping layer of CYTOP;

FIGS. 7A and 7B depict temperature-dependent mobility and impurity studies of the effect of capping a graphene layer with a fluoropolymer;

FIG. 8 depicts the effect of capping with fluoropolymer on highly doped monolayer graphene FETs;

FIGS. 9A-9C show the electrical characteristics of mono-layered graphene FET employing CYTOP (FIG. 9A), Teflon-AF (FIG. 9B) and F₁₆CuPc (FIG. 9C);

FIG. 10 shows the normalized resistance of mono-layered graphene by capping with fluoropolymer;

FIG. 11 shows the electrical characteristics of as-deposited mono-layered graphene FET without capping with CYTOP, with capping with CYTOP, and after removal of CYTOP;

FIG. 12 depicts the field-effect mobility improvement and Dirac voltage changes caused by capping a graphene layer with a fluoropolymer;

FIG. 13 depicts the effect of removing a fluoropolymer from a fluoropolymer coated graphene layer;

FIGS. 14A and 14B depict current saturation behavior in various coated and uncoated FETs; and

FIG. 15 depicts the effect of forming a fluoropolymer layer on a molybdenum disulfide layer.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

It is to be understood the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

Described herein are improved graphene semiconductor devices (e.g., FETs) formed by capping with a fluoropolymer and/or a hydrofluoropolymer (e.g., CYTOP and TEFLON-AF). The conductivity at the Dirac point is reduced and the mobility is increased, leading to an improvement in the on-off current ratio to ˜10. Remarkably, the key graphene device metrics are improved including electron-hole transport symmetry, Dirac voltage, and reduced impurity doping. It is believed that the effect described is not associated with graphene doping, but it is apparently a combination of phenomena resulting from ordered polar groups that form when fluoropolymer films are deposited on graphene. We note that, in general, attempts to coat graphene with inorganic dielectrics such as silicon dioxide and aluminum oxide have not resulted in an improvement in electrical characteristics. Importantly, these results have been achieved in graphene grown by wafer-scale chemical vapor deposition (CVD) process. From a practical standpoint, this is a significant advance in that it offers a clear path to improve the performance characteristics of graphene FETs in which the active material is grown by wafer-scale CVD. CVD graphene is the most promising method of realizing large area graphene and in adapting graphene for silicon CMOS and flexible electronics. The improved mobilities and reduced conductivities will open up the range of applications for graphene circuitry.

In an embodiment, a semiconductor device includes a substrate, a graphene layer disposed on the substrate; and a fluoropolymer or hydrofluoropolymer layer disposed on the graphene layer. In some embodiments the substrate comprises a silicon substrate. A silicon oxide layer may be disposed on the silicon substrate, between the silicon substrate and the graphene layer. The semiconductor device is, in some embodiments, a transistor (e.g., a field-effect transistor). Other semiconductor devices are also contemplated. The substrate may be silicon, glass, or a polymeric substrate.

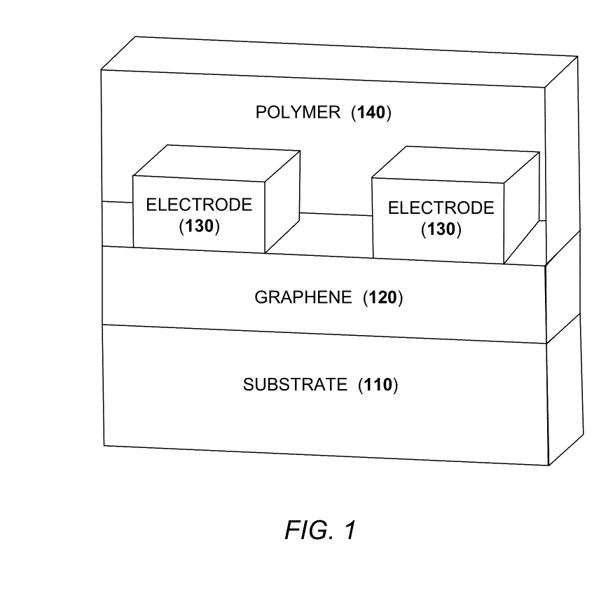

FIG. 1 depicts a schematic diagram of an exemplary transistor 100 that includes a coated graphene layer 120. Transistor 100 includes a substrate 110 and a graphene layer 120 disposed on the substrate. Transistor may include source/drain electrodes 130. Graphene layer 120 and source/drain electrodes 130 may be coated with a fluoropolymer or hydrofluoropolymer layer 140.

The term fluoropolymer, as used herein, is a polymeric material that is composed of one or more fluorocarbons. Fluorocarbons (also known as perfluorocarbons) are organofluorine compounds that do not contain any hydrogen atoms, the hydrogen atoms being replaced by fluorine atoms. The term hydrofluoropolymer, as used herein, is a polymeric material that is composed of one or more hydrofluorocarbons. Hydrofluorocarbons are organofluorine compounds that contain hydrogen atoms and fluorine atoms. As used herein the term “ether fluoropolymer” refers to a fluoropolymer that includes oxygen, which is present in the form of ether bonds. Examples of fluoropolymers include, but are not limited to: polyvinylfluoride (PVF); polyvinylidene fluoride (PVDF); polytetrafluoroethylene (PTFE); polychlorotrifluoroethylene (PCTFE); perfluoroalkoxy polymer (PFA); fluorinated ethylene-propylene (FEP); polyethylenetetrafluoroethylene (ETFE); polyethylenechlorotrifluoroethylene (ECTFE); Perfluorinated Elastomer [Perfluoroelastomer]) (FFPM/FFKM); Fluorocarbon [Chlorotrifluoroethylenevinylidene fluoride]) (FPM/FKM); Perfluoropolyether (PFPE), Perfluorosulfonic acid (PFSA); perfluoropolyoxetane; perfluoropolydioxole (PFPD, e.g., Teflon AF); and perfluoropolytetrafluorofuran (e.g., CYTOP). Of these examples, the following are ether fluoropolymers: perfluoroalkoxy polymer (PFA); (FPM/FKM); Perfluoropolyether (PFPE); perfluoropolyoxetane; perfluoropolydioxole (PFPD, e.g., Teflon AF); and perfluoropolytetrafluorofuran (e.g., CYTOP). Preferred fluoropolymers include a copolymer of perfluoro-2,2-methyl-1,3-dioxole and perfluoro-2-methylene-4-methyl-1,3-dioxolane. (Teflon AF) and the fluoropolymer CYTOP (from Asashi Glass Co.).

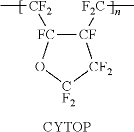

In some embodiments, the graphene layer is monolayer graphene. Monolayer graphene may be formed by a number of methods including but not limited to mechanical exfoliation, epitaxy, and chemical vapor deposition. Preferably, low-pressure chemical vapor deposition (LPCVD) is used to form monolayer graphene. In an embodiment, a process for forming a monolayer graphene layer includes: forming a graphene layer on a copper coated Si/SiO₂ substrate transferring the graphene layer to a Si/SiO₂ substrate using a wet-transfer process.

The graphene layer, after transfer to the Si/SiO₂ substrate, may be patterned and etched to allow formation of the elements of the semiconductor device (e.g., source/drain electrodes). The resulting graphene based semiconductor device may be coated with the fluoropolymer. In an embodiment, coating of the graphene based semiconductor device may be performed by spin-coating using a solution of the fluoropolymer in an appropriate solvent. In some embodiments, the resulting fluoropolymer layer is annealed to complete formation of the fluoropolymer layer.

In some embodiments a fluoropolymer or hydrofluoropolymer layer is applied on both sides of the graphene layer. In such embodiment, a first fluoropolymer or hydrofluoropolymer layer may be placed on a substrate, below the graphene layer. A second fluoropolymer or hydrofluoropolymer may be formed on a top surface of the graphene layer.

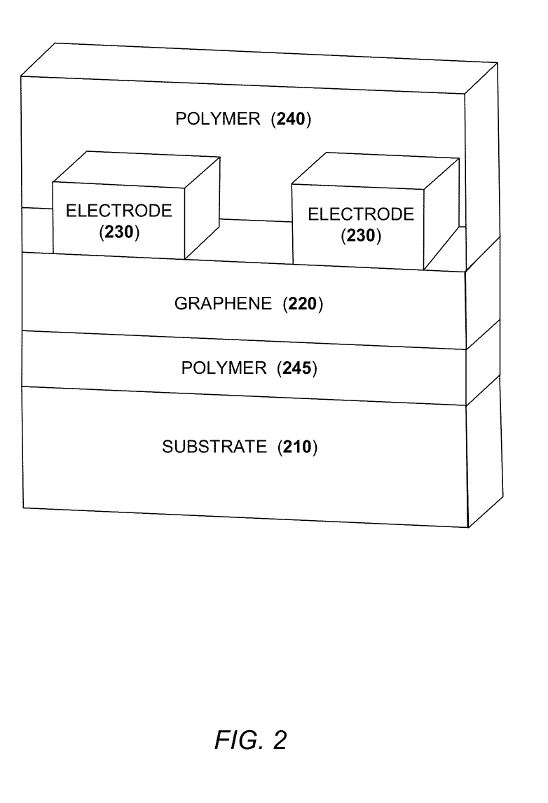

FIG. 2 depicts a schematic diagram of an exemplary transistor 200 that includes a graphene layer 120 having top and bottom fluoropolymer or hydrofluoropolymer layers. Transistor 200 includes a substrate 210 and a first fluoropolymer or hydrofluoropolymer layer 245 disposed on the substrate. Graphene layer 220 is disposed on first fluoropolymer or hydrofluoropolymer layer 245. Transistor may include source/drain electrodes 230. Graphene layer 220 and source/drain electrodes 230 may be coated with a second fluoropolymer or hydrofluoropolymer layer 240.

In another embodiment, a semiconductor device includes a silicon substrate; a silicon oxide layer disposed on the silicon substrate; a molybdenum sulfide (MoS₂) layer disposed on the silicon oxide layer; and a fluoropolymer layer disposed on the molybdenum sulfide layer. The semiconductor device is, in some embodiments, a transistor (e.g., a field-effect transistor). Other semiconductor devices are also contemplated.

The molybdenum sulfide layer, after transfer to the Si/SiO₂ substrate, may be patterned and etched to allow formation of the elements of the semiconductor device (e.g., source/drain electrodes). The resulting molybdenum sulfide based semiconductor device may be coated with a fluoropolymer or hydrofluoropolymer layer. In an embodiment, coating of the molybdenum sulfide based semiconductor device may be performed by spin-coating using a solution of the fluoropolymer or hydrofluoropolymer layer in an appropriate solvent. In some embodiments, the resulting fluoropolymer or hydrofluoropolymer layer is annealed to complete formation of the fluoropolymer or hydrofluoropolymer layer.

In some embodiments, a fluoropolymer or hydrofluoropolymer layer may be applied to various patterned graphenes. Patterned graphene, as used herein, refers to graphene that is a substantially 2-dimensional structure having a thickness of less than 100 nm. Exemplary patterned graphene includes graphene sheets, graphene films and graphene nanoribbons. Nanoribbons of graphene, for example, can have an energy gap leading to improved on/off ratios. However, the patterning process used to form graphene nanoribbons introduces defects and impurities. The fluoropolymer and hydrofluoropolymer coatings can be used to mitigate the deleterious effects of the process steps involved in patterning the graphene into nanoribbons. Thus, in one embodiment, a patterned graphene (e.g., a graphene nanoribbon) may be coated with a fluoropolymer or hydrofluoropolymer layer in a manner similar to the techniques described above. The coated patterned graphene exhibits improved electronic characteristics.

### Examples and Data

The following examples are included to demonstrate preferred embodiments of the invention. It should be appreciated by those of skill in the art that the techniques disclosed in the examples which follow represent techniques discovered by the inventor to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

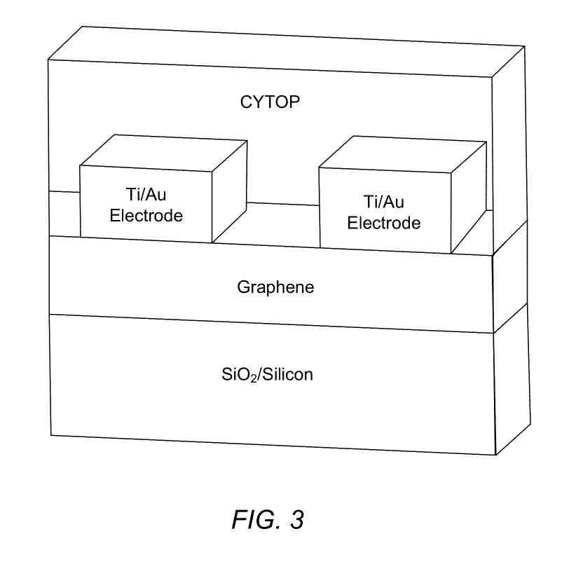

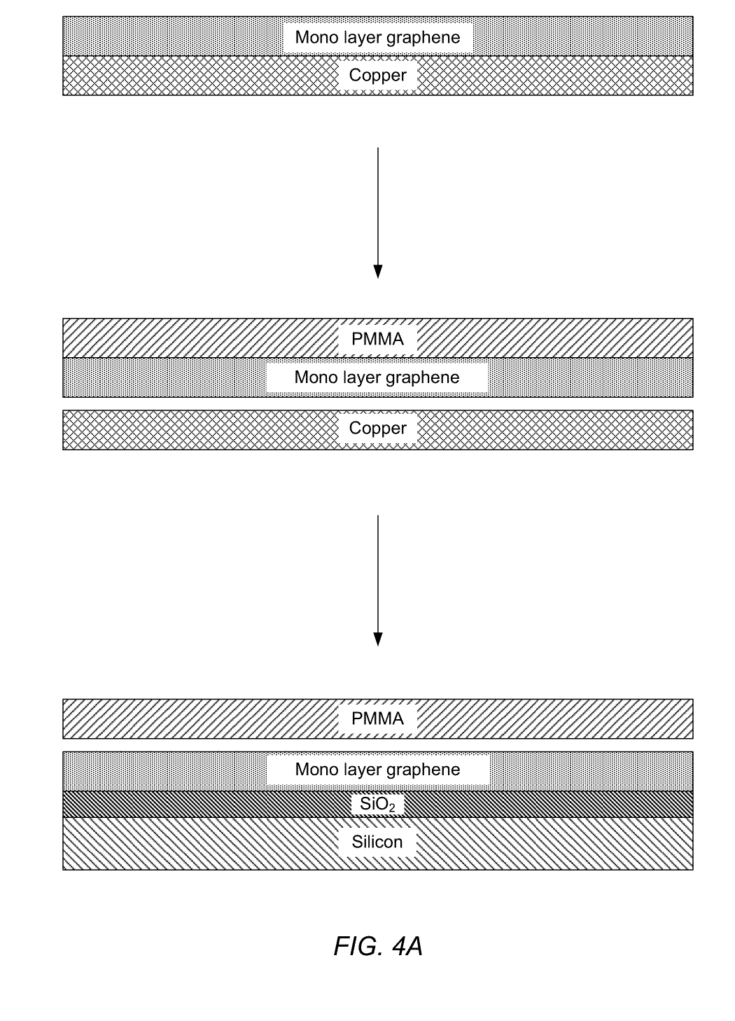

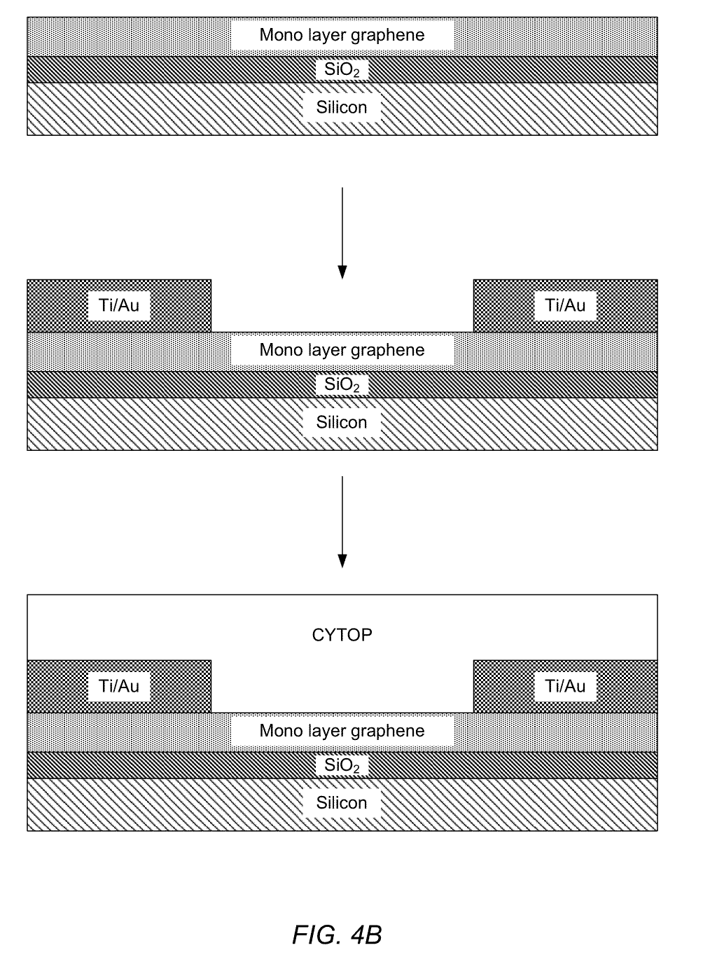

FIG. 3 shows the schematic cross-section of a monolayer silicon/silicon oxide graphene FET after capping with the fluoropolymer, CYTOP. The process for forming a monolayer graphene FET with a fluoropolymer cap is outlined in FIGS. 4A and 4B. As a first step, good-quality monolayer graphene films were synthesized on 500 nm thick e-beam evaporated copper films grown on silicon/silicon dioxide (Si/SiO2) substrates, by the low-pressure chemical vapor deposition (LPCVD) as described in Tao, L.; Lee, J.; Chou, H.; Holt, M.; Ruoff, R. S.; Akinwande, D. ACS Nano 2012, 6, 2319 and Lee, J.; Tao, L.; Hao, Y.; Ruoff, R. S.; Akinwande, D. Appl. Phys. Lett. 2012, 100, 152104, both of which are incorporated herein by reference. In brief, the copper-coated Si/SiO₂ substrates were first annealed for 5 min at 1000° C. in hydrogen-saturated ambient. The hydrogen gas was purged away at the end of the annealing process and ultrahigh purity (99.99%) methane was circulated at a flow rate of 10 sccm for 5 min during the growth process. This results in the formation of a monolayer graphene on copper. After growth, the chamber was slowly cooled to below 180° C. before unloading of samples. Graphene on copper films were spin-coated with poly(methyl methacrylate) (PMMA) at 4000 rpm for 1 min.

The graphene films were then transferred to the second Si/SiO₂ substrate by a conventional wet-transfer process. In the wet-transfer process, the PMMA/graphene/copper layer was detached from the underlying Si/SiO₂ by etching away the sacrificial oxide in buffered oxide etch (6:1). Following this, the copper layer below graphene was etched in dilute ammonium persulfate solution to leave a free-standing film of graphene coated with PMMA. This free-standing film is transferred to a water bath where it is made to adhere to a fresh Si/SiO₂ substrate. This substrate possesses a 285 nm thick SiO2 layer that subsequently functions as the gate insulator in FET devices. The PMMA is then removed with acetone. (See FIG. 4A for a schematic diagram of this sequence)

Oxygen plasma reactive-ion-etching (RIE) was used to pattern the active channel region, to remove the superfluous graphene and to ensure device isolation. Source/drain electrodes were patterned by electron-beam lithography and lift-off. The titanium/gold (2.0 nm/50 nm) bilayers that form the source/drain contacts were deposited by thermal evaporation under high vacuum. Deposition of good quality titanium and gold in high vacuum conditions (˜1×10⁻⁷ Torr) are key to realizing low-resistance electrical contacts. The samples were kept in high vacuum for 2 days to minimize impurity incorporation. Monolayer graphene FETs fabricated as described above feature possess a channel width of 5 μm and a channel length of 1 μm. After completing the entire fabrication of graphene FETs, Raman spectra were measured. The full width at halfmaximum (fwhm) of the 2D peak is ˜29 cm⁻¹. The intensity ratio between 2D and G peaks is 2.8. The D peak intensity is small or negligible. These results indicate that the monolayer graphene in the FET is of high material quality.

A 90 nm thick layer of the fluoropolymer, CYTOP (Asahi Glass Co.) was deposited by spin-coating a diluted CYTOP solution (CYTOP:CYTOP solvent=1:10) on monolayer graphene and annealed gradually from 30 to 180° C. for over a span of 1 h in a nitrogen atmosphere. A 140 nm thick layer of Teflon-AF (Dupont Co.) was also spin-coated with as-supplied Teflon-AF solution on monolayer graphene. The samples were annealed gradually from 30 to 300° C. for over a span of 1 h in a nitrogen atmosphere. In order to remove the CYTOP from graphene FETs, the samples were immersed in a CYTOP solvent for 24 h. DC measurements for the device characteristics were carried out using an Agilent 4155C semiconductor parameter analyzer. (See FIG. 4B for a schematic diagram of this sequence)

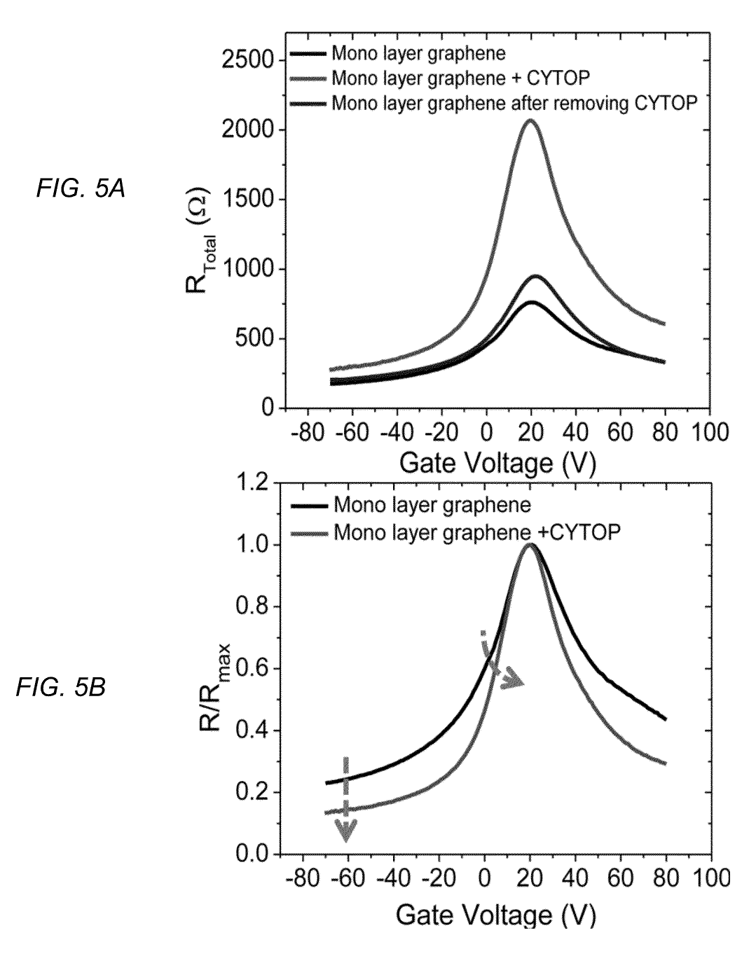

FIG. 5A shows the transfer characteristics of as-deposited monolayer graphene FET without capping with CYTOP, with capping with CYTOP, and after removal of CYTOP. The drain-source voltage is 0.1 V during the sweep of the gate voltage from −70 to 80 V. It is generally observed that device characteristics such as on-state current, field-effect mobility and on-off current ratio in graphene FETs are reduced after the deposition of most dielectrics materials on graphene due to charge scattering. It is observed that in the present case, the off-state current (at the Dirac point) is decreased substantially, resulting in a net improvement in the on-off current ratio with the use of CYTOP. This is illustrated more clearly in FIG. 5B, which shows that the on-off current ratio is improved from 5 to 10 after depositing CYTOP on graphene FETs. In addition, the field-effect mobility was improved from 1731 to 3606 cm²/(V-s), width-normalized contact resistance is not appreciably altered from ˜400 Ωμm and residual carrier density no is reduced. The residual carrier density and the field-effect mobility are mainly determined from the minimum current at the Dirac point and the slope from the curves, respectively. The results indicate that electrical device characteristics of graphene FETs are significantly improved through the interaction between fluoropolymer and monolayer graphene, which is different from the interaction of graphene with most dielectrics such as silicon dioxide, aluminum oxide and hafnium oxide. When the CYTOP layer was removed by using CYTOP solvent from monolayer graphene FETs, the transfer characteristic tends to return to its initial state (i.e., that of monolayer graphene before CYTOP deposition), as shown in FIG. 5A. There are spots where the CYTOP remains despite attempts to remove it. This results in the electrical characteristics reverting close to (but not exactly the same) as that of the graphene FETs before CYTOP application. The electronic properties of graphene can be tuned favorably using a capping layer of a material such as CYTOP and the interaction between graphene and CYTOP is weak enough to permit easy removal of CYTOP.

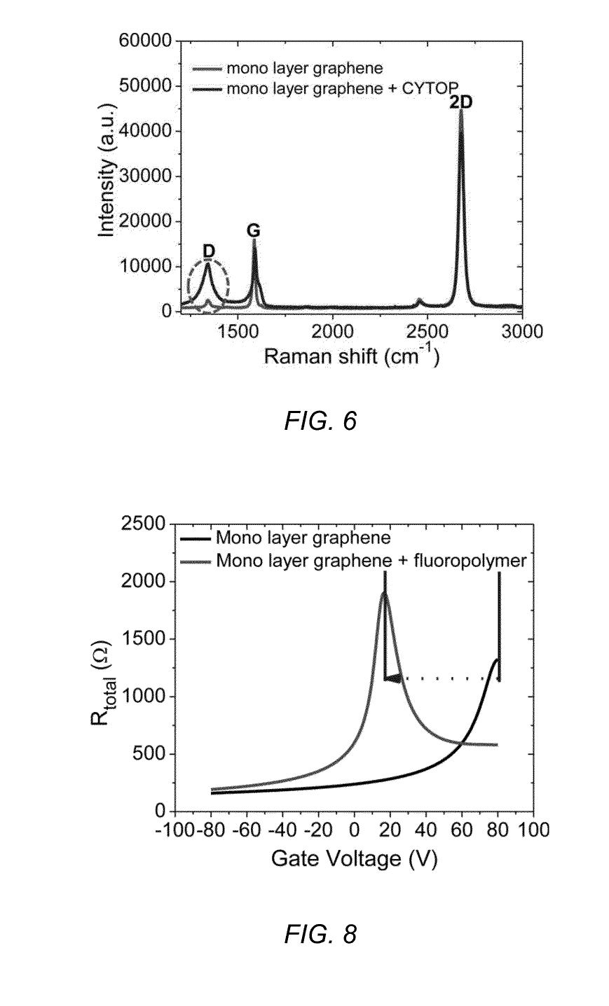

Raman spectra were measured with a 442 nm blue laser on monolayer graphene capped with CYTOP. FIG. 6 shows the change in the Raman spectrum of monolayer graphene produced by the capping layer of CYTOP. The intensity of the D band at 1350 cm⁻¹ was strongly increased after capping the graphene with CYTOP. At the same time, the intensity of the 2D band at 2700 cm⁻¹ and the G band at 1580 cm⁻¹ were slightly decreased. The C—F bonds in the CYTOP structure are very polar and graphene is a highly polarizable material. The electronic interaction between the dipoles in the CYTOP and the graphene can modify its electronic properties significantly, leading to the effects that we observe. We note that with nonpolar organic capping layers such as pentacene, no significant changes in the electrical properties of graphene FETs are observed. We have verified our hypothesis in the case of a second fluoropolymer, Teflon-AF possessing polar C—F bonds, which also results in a marked improvement in electrical properties of graphene upon capping. The origin of this improvement is believed to be in the strongly polar nature of the C—F chemical bond found in the capping materials we have employed together with the tendency of these materials to self-organize upon heat treatment such that there is an oriented layer of dipolar C—F bonds at the interface with graphene. This dipole layer results in a reduction of the dimensionless fine structure constant (α).30 A reduction in fine structure constant improves the mobility, which is limited by long-range scattering by charged impurities while simultaneously, the minimum conductivity, determined by short-range scattering, decreases. This results in an improved on-off ratio, which has so far been a problem for graphene FETs.

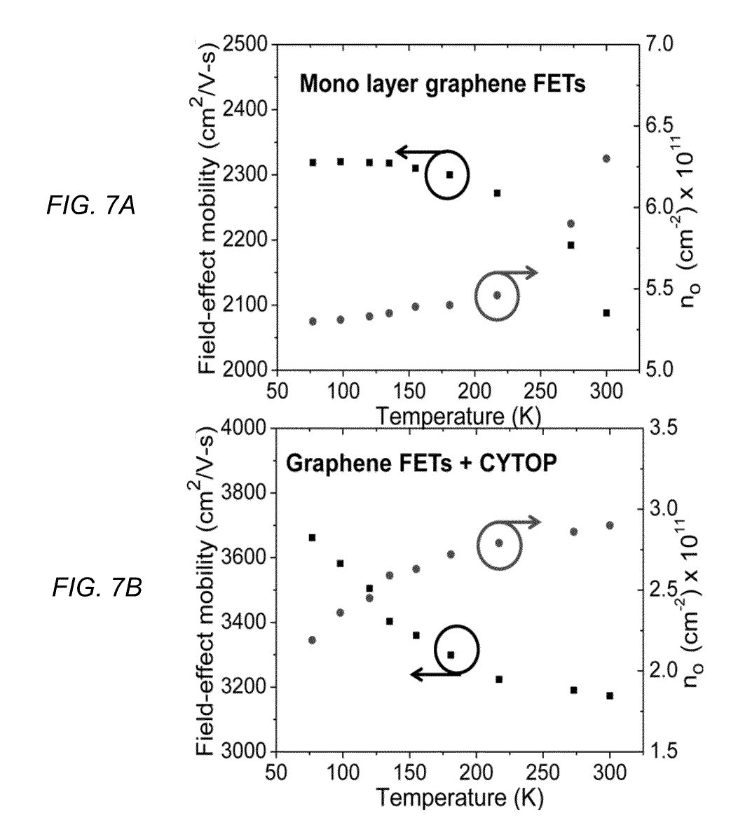

Temperature-dependent mobility and impurity studies also show that with capping, the impurity scattering limited mobility continues to increase with reducing temperature which is accompanied by a reduction in no as shown in FIGS. 7A and 7B. The residual carrier concentration is reduced to ˜2.8×10¹¹ cm⁻² at room temperature when employing the capping layer of a fluoropolymer on graphene. The CYTOP dipoles could also break the symmetry between the A and B sublattices in graphene, leading to the development of a small energy gap, which is also consistent with our results. The effect of capping with fluoropolymer on highly doped monolayer graphene FETs is shown in FIG. 8. Before coating, the graphene FETs possess a very positive Dirac voltage of 80 V and asymmetric electron and hole transport. Upon coating with the Teflon-AF and annealing at 300° C., we observe a remarkable shift in the Dirac voltage toward zero with shift magnitudes in excess of 60 V. In addition, electron and hole transport becomes more symmetric and the on-off current ratio improved from 6 to 8 as well as the field-effect mobility was increased from 1700 to 3452 cm²/V-s without change in width-normalized contact resistance. In addition, the residual carrier density no is reduced from 2.3×1012 to 4.6×1011 cm⁻². We also observed a shift in Dirac voltage of around 50 V toward zero for graphene FETs capped with CYTOP. The fluorocarbon capping method is therefore a way to restore or greatly improve the properties of graphene that are otherwise nonideal when formed using a combination of CVD and transfer methods.

It is meaningful that a significant favorable modification of electronic properties of monolayer graphene FETs can occur with the introduction of the selected organic material without a complicated fluorination fabrication process. A similar effect of capping layer of fluorinated semiconductor, hexadecafluorocopperphthallocyanine (F₁₆CuPc) was observed on monolayer graphene FETs. Compared to the plain graphene FET, capping with F₁₆CuPc improved on-off current ratio from 3 to 5 as well as the field-effect mobility from 1292 to 1367 cm²/(V-s). High deposition temperatures will lead to a more crystalline, π-stacked phthalocyanine structure with the fluorinated periphery presenting to the graphene interface.

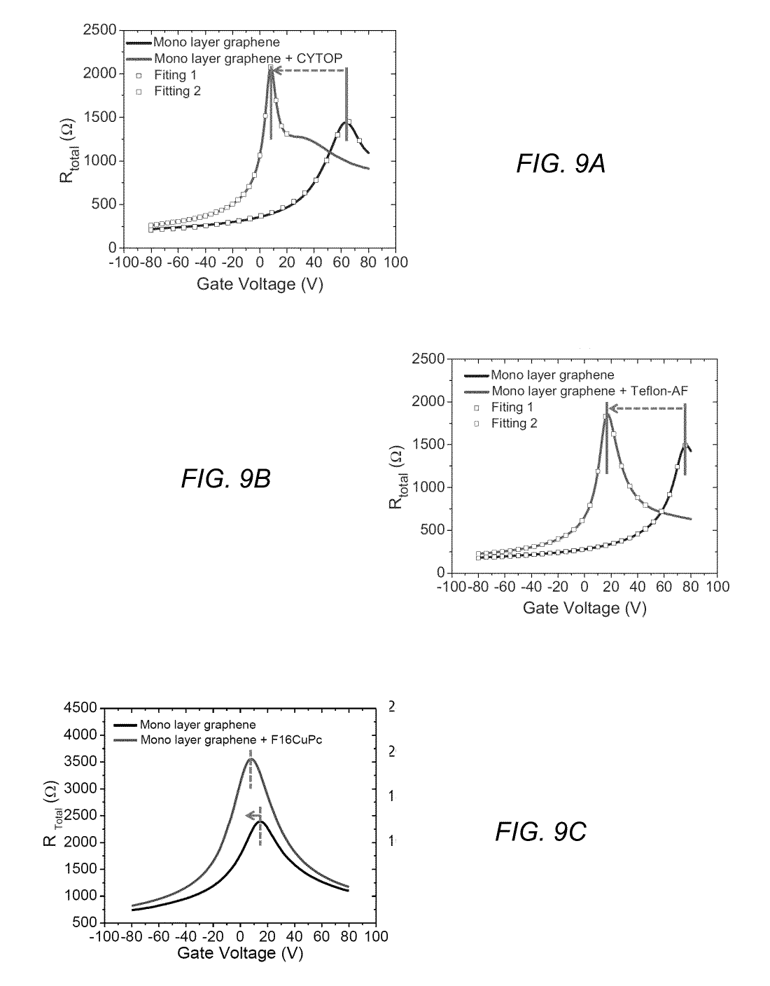

FIGS. 9A-9C show the electrical characteristics of mono-layered graphene FET employing CYTOP (FIG. 9A), Teflon-AF (FIG. 9B) and F₁₆CuPc (FIG. 9C), at a drain-source voltage of 0.1 V, with the gate bias swept from −80 to 80 V. Also shown in the figure are the electrical characteristics of the original mono-layered graphene FETs before coating with the fluoropolymer or fluorinated semiconductor. Before coating, the graphene FETs possess a very positive Dirac voltage of 64-76 V owing to the chemical contamination and undesirable doping during the wet transfer process, and asymmetric electron and hole transport. Upon coating with the fluoropolymer and annealing, a remarkable shift in the Dirac voltage toward zero with shift magnitudes in excess of 60 V is observed. In addition, electron and hole transport becomes more symmetric and the ON-OFF current ratio is improved to about 8. In contrast very little shift in the Dirac voltage is seen between the uncoated and fluorinated semiconductor coated FETs (FIG. 9C).

In order to extract device key parameters from the electrical characteristics, a diffusive transport model based on total resistance of the graphene device was employed. This method is widely accepted in the graphene community. Original mono-layered graphene FETs possess field-effect mobility of 1750 cm²/V-s, no of 1×1012 cm⁻² and width-normalized contact resistance is ˜375 Ωμm. After capping with CYTOP and Teflon-AF, the field-effect mobility is increased to 2628 cm²/V-s and 3066 cm²/V-s and nₒ is decreased to 5.8×1011 cm⁻² and 4.8×1011 cm⁻², respectively without any appreciable change in the contact resistance. It is generally observed that device characteristics in graphene FETs are not changed significantly or even degraded after the deposition of most inorganic dielectric materials on graphene due to charge scattering. However, we observe that the field-effect mobility is increased and no is decreased with the use of fluoropolymer capping. It must be noted that the fluorocarbon capping method is a way to restore improve the properties of graphene layers that are otherwise nonideal when formed using a combination of CVD and transfer methods.

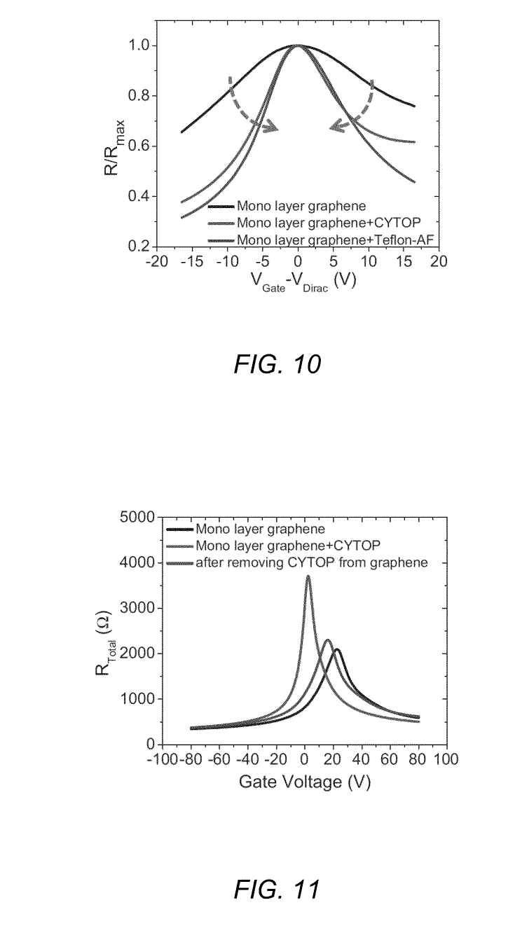

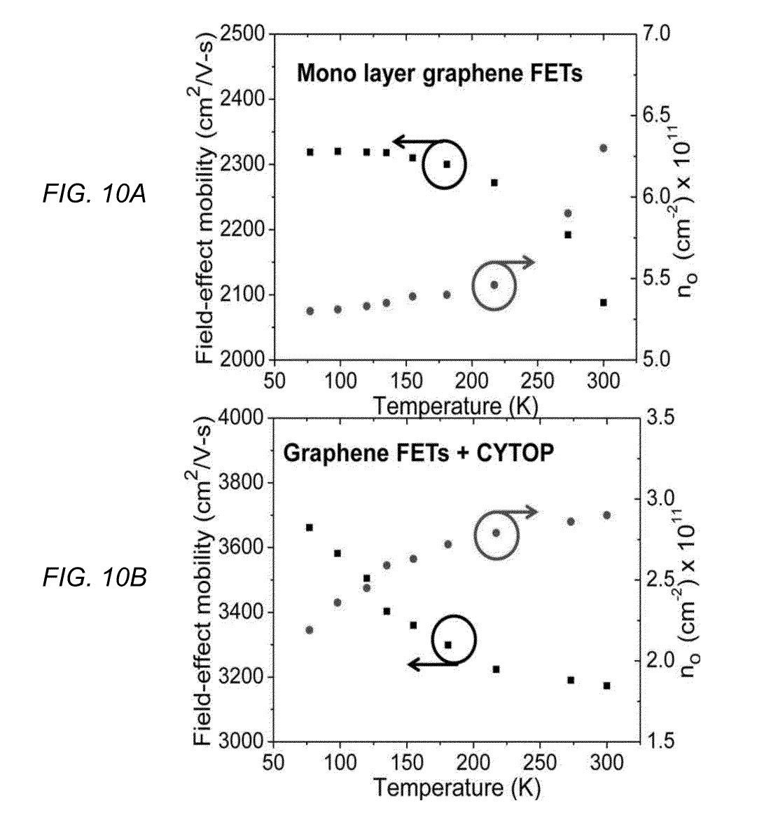

Since mono-layered graphene has no bandgap, the drain current in graphene FETs cannot be turned off completely by the gate bias, in contrast with silicon-based devices. FIG. 10 shows the normalized resistance of mono-layered graphene by capping with fluoropolymer. Compared to the original graphene FET, the ON-OFF current ratio was improved by a factor of two with the use of fluoropolymer capping. In order to improve device characteristics of graphene FETs, suspended structures and hexagonal boron nitride (h-BN) substrate have been previously employed. However, these methods are not currently scalable, unlike the wafer-scaled SiO₂ substrate described herein.

FIG. 11 shows the electrical characteristics of as-deposited mono-layered graphene FET without capping with CYTOP, with capping with CYTOP, and after removal of CYTOP. The ON-OFF current ratio is improved from 6 to 10 after depositing CYTOP on graphene FETs. In addition, the field-effect mobility was improved from 2088 to 3173 cm²/V-s. The changes are not a result of outgassing since the effects we observe and report are reversible. When the CYTOP layer was removed by using CYTOP solvent from graphene FETs, the characteristic tends to return to its initial state (i.e. that of mono-layered graphene before CYTOP deposition), as shown in FIG. 8. These results mean that the electronic properties of graphene can be tuned favorably using a capping layer of a material such as CYTOP and the interaction between graphene and CYTOP is weak enough to permit easy removal of CYTOP.

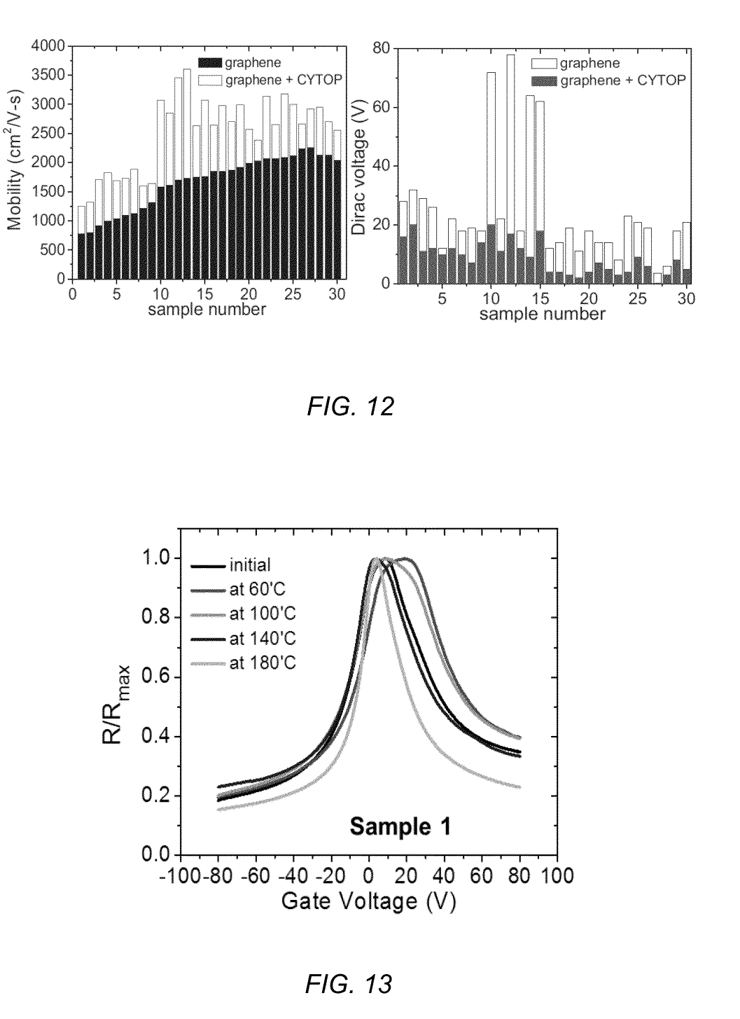

Device statistics (30 samples) conclusively prove the improvement as illustrated in FIG. 12, which shows the field-effect mobility improvement and Dirac voltage shifts toward 0 V. These devices have been fabricated in different batches at different times. All of the graphene FETs are improved after using the fluoropolymer encapsulation layer. After capping with CYTOP, the average value of mobility is improved by a factor of 1.5 and that of Dirac voltage is decreased from 25 V to 8 V.

It was also observed that the electrical properties of CYTOP-coated graphene steadily improve with annealing temperature (in the range 60-180° C.) demonstrating that the side-chain alignment that accompanies such annealing is a key factor in the transformation of electrical properties. It is noteworthy that if the CYTOP is removed after the annealing, then the original graphene characteristics are recovered indicating reversible non-covalent interactions (FIG. 13).

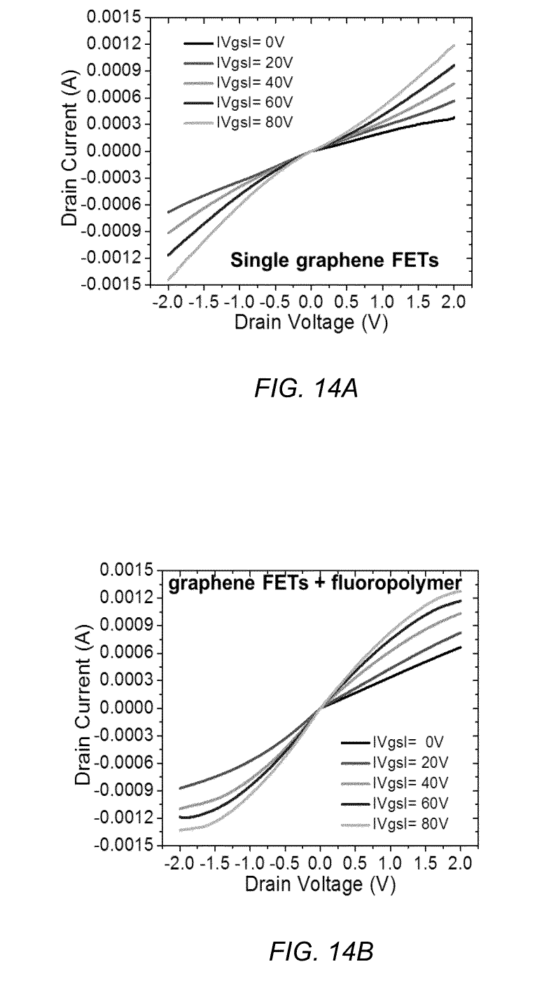

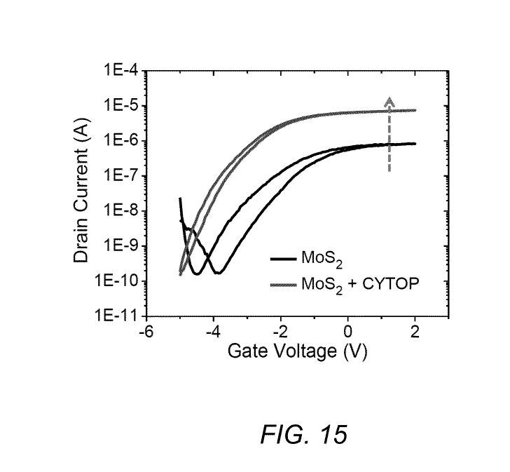

We also note that we observe current saturation behavior in these FETs which can afford current sources and analog/RF electronics (FIGS. 14A and 14B). The favorable effects of capping with fluorpolymers are also observed in MoS₂, in which the on-current is increased by more than 10× (FIG. 15).

The capping materials that we have chosen all possess C—F bonds and processing conditions have been employed that results in the materials ordering in a manner that results in a strong net dipole moment at the interface with graphene. Additional experiment and theoretical work is being done to understand these effects in more detail and will be reported elsewhere. The fact that the strength of this interaction is dependent on the annealing temperature of the CYTOP and Teflon-AF also suggests that annealing improves the ordering of the fluoropolymer and consequently the total dipole strength. In the case of the two fluoropolymers postdeposition annealing (at temperatures up to 300° C.) was employed to enable material reorganization and the side chain alignment that is commonly observed in these materials. For the organic semiconductor, F₁₆CuPc, material deposition was performed at elevated temperatures (up to 200° C.). Previous work has shown that such elevated deposition temperatures results in the best ordered materials resulting in relatively high mobility in these semiconducting films. It can be clearly observed that the electrical properties of CYTOP-coated graphene steadily improve with annealing temperature (in the range 60-180° C.) demonstrating that the side-chain alignment that accompanies such annealing is a key factor in the transformation of electrical properties. It is noteworthy that if the CYTOP is removed after the annealing, then the original graphene characteristics are recovered indicating reversible noncovalent interactions. While many of these results can be explained in terms of a modification of the fine structure constant, we note that graphene is very polarizable and changes to the electronic structure and, consequently transport properties, can result from having oriented dipoles topping the graphene. Additionally, we have modified the electronic environment on only one side of the graphene monolayer. If both interfaces have highly polar bonds juxtaposed, then the favorable effects we report can be further enhanced.

In summary, we have shown that the electrical characteristics of graphene are favorably altered by capping with the fluoropolymer CYTOP and Teflon-AF. The on-off current ratio is improved and the Dirac voltage shifted toward zero. The residual carrier density no is reduced and the mobility increased by as much as a factor of 2. We hypothesize that this alteration in electrical properties is a result of electronic polarization of the graphene by local C—F dipoles in the fluoropolymer. The strength of this interaction is dependent on the annealing temperature, which influences the ordering of the polymer and consequently the local dipole field. The approach we described offers a way to transform the electrical characteristics of graphene making it potentially more useful for a wider range of electronic applications.

In this patent, certain U.S. patents, U.S. patent applications, and other materials (e.g., articles) have been incorporated by reference. The text of such U.S. patents, U.S. patent applications, and other materials is, however, only incorporated by reference to the extent that no conflict exists between such text and the other statements and drawings set forth herein. In the event of such conflict, then any such conflicting text in such incorporated by reference U.S. patents, U.S. patent applications, and other materials is specifically not incorporated by reference in this patent.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A semiconductor device comprising:
a substrate;
a graphene layer disposed on the substrate; and
a fluoropolymer or a hydrofluoropolymer layer disposed on the graphene layer.

2. The semiconductor device of claim 1, wherein the semiconductor device is a field-effect transistor.

3. The semiconductor device of claim 1, wherein the graphene layer is monolayer graphene.

4. The semiconductor device of claim 1, wherein the device comprises a fluoropolymer layer, and wherein the fluoropolymer layer is an ether fluoropolymer.

5. The semiconductor device of claim 1, wherein the device comprises a fluoropolymer layer, and wherein the fluoropolymer layer is a copolymer of perfluoro-2,2-methyl-1,3-dioxole and perfluoro-2-methylene-4-methyl-1,3-dioxolane (Teflon AF).

6. The semiconductor device of claim 1, wherein the device comprises a fluoropolymer layer, and wherein the fluoropolymer layer is CYTOP.

7. The semiconductor device of claim 1, wherein the substrate comprises silicon.

8. The semiconductor device of claim 1, wherein the substrate comprises silicon having a silicon oxide layer disposed between the silicon and the graphene layer.

9. The semiconductor device of claim 1, wherein the substrate is glass.

10. The semiconductor device of claim 1, wherein the substrate is a polymer.

11. The semiconductor device of claim 1, wherein the device comprises a first fluoropolymer layer or hydrofluoropolymer layer disposed on the substrate between the substrate and the graphene layer, and wherein the device comprises a second fluoropolymer layer or hydrofluoropolymer layer disposed on the graphene layer.

12. A method of forming a semiconductor device comprising:
forming a graphene layer on a substrate; and
forming a fluoropolymer layer or a hydrofluoropolymer layer on the graphene layer.

13. The method of claim 12, wherein the substrate comprises silicon having a silicon oxide layer which is positioned between the silicon and the graphene layer.

14. The method of claim 12, wherein forming the graphene layer comprises:
forming a graphene layer on a copper substrate;
forming a polymer layer on the graphene layer;
separating the polymer layer and graphene layer from the copper substrate;
transferring the polymer layer and graphene layer to the substrate.

15. The method of claim 12, wherein forming a fluoropolymer layer or hydrofluoropolymer layer on the graphene layer comprises applying a solution of the fluoropolymer or hydrofluoropolymer by a spin coating process.

16. A semiconductor device comprising:
a substrate;
a molybdenum disulfide layer disposed on the substrate; and
a fluoropolymer layer or hydrofluoropolymer layer disposed on the molybdenum disulfide layer.

17-28. (canceled)
